(19) United States
(12) Patent Application Publication
(10) Pub. No.: US 2025/0342895 A1
(43) Pub. Date: Nov. 6, 2025

(54) SEMICONDUCTOR DEVICE AND ELECTRONIC APPARATUS

(71) Applicant: SONY SEMICONDUCTOR SOLUTIONS CORPORATION, KANAGAWA (JP)

(72) Inventors: Yoshihiko KAJIYA, KANAGAWA (JP); Isao NARITAKE, KANAGAWA (JP); Tomoko SHIMADA, KANAGAWA (JP); Yasuo KANDA, KANAGAWA (JP); Chiaki SEKI, KANAGAWA (JP)

(21) Appl. No.: 18/871,083

(22) PCT Filed: May 26, 2023
(86) PCT No.: PCT/JP2023/019611

§ 371 Date: Dec. 2, 2024

(30) Foreign Application Priority Data
Jun. 10, 2022 (JP) 2022-094330

(51) Int. Cl. G11C 17/16; G11C 5/06; H10B 20/25

(52) U.S. Cl. CPC G11C 17/165; G11C 5/063; H10B 20/25

(57) ABSTRACT

A semiconductor device according to an aspect of the present disclosure includes: a plurality of fuse elements; and a selection element that is provided in common to the plurality of fuse elements and switches the plurality of fuse elements between a conduction target and a non-conduction target.

### FIELD

The present disclosure relates to a semiconductor device and an electronic apparatus.

### BACKGROUND

In One Time Programmable semiconductor devices, for example, a fuse element (Metal FUSE) in which writing is performed by fusing a metal using a laser and an electrical fuse element (eFUSE) in which writing is performed by irreversibly changing an electrical resistance (value) by changing a composition of a wiring material are used as memory elements (see, for example, Patent Literature 1). In particular, the electrical fuse element can perform writing by electrical control, and thus, there is an advantage that usability is good.

Normally, in the electrical fuse element, the occupied area and the amount of current flowing at the time of changing the resistance are large as compared with a variable resistance semiconductor device whose resistance value is electrically changed, but a structure is simple so that an additional step of a manufacturing process is hardly required. For this reason, the electrical fuse element is not a so-called general-purpose memory, and is often used to store additional information. For example, the electrical fuse element is used for a purpose of adjusting (trimming) characteristics of a semiconductor device (integrated circuit), a purpose of selecting a redundant circuit, a purpose of storing characteristic values and other information in a rewritable manner after completion of a device, or the like.

In general, a memory cell utilizing the electrical fuse element has a form in which one blow transistor (BlowTr) is connected to one electrical fuse element. In the electrical fuse element, the resistance value is remarkably increased by fusing of a conductive layer, breakdown of an insulating film, or the like using a current flowing when the blow transistor is turned on (ON). By this operation, the memory cell representing a binary value can be achieved. Note that it is not possible to decrease resistance of a portion where the resistance has been increased by the fusing of the conductive layer, the breakdown of the insulating film, or the like, and thus, writing to the memory cell is performed only once.

### CITATION LIST

### Patent Literature

### Patent Literature 1: JP H01-8643 A

### SUMMARY

### Technical Problem

However, since one blow transistor is connected to one electrical fuse element according to the above-described electrical fuse element, the blow transistors are required as many as the number of electrical fuse elements. For this reason, the number and occupied area (for example, installation area) of selection elements (for example, switch elements) such as the blow transistor become large.

Therefore, the present disclosure provides a semiconductor device and an electronic apparatus that are capable of reducing the number and occupied area of selection elements.

### Solution to Problem

A semiconductor device according to an aspect of the present disclosure includes: a plurality of fuse elements; and a selection element that is provided in common to the plurality of fuse elements and switches the plurality of fuse elements between a conduction target and a non-conduction target.

An electronic apparatus according to an aspect of the present disclosure includes a semiconductor device, wherein the semiconductor device includes: a plurality of fuse elements; and a selection element that is provided in common to the plurality of fuse elements and switches the plurality of fuse elements between a conduction target and a non-conduction target.

### BRIEF DESCRIPTION OF DRAWINGS

FIG. 1 is a diagram illustrating a configuration example of a semiconductor memory device according to an embodiment.

FIG. 2 is a diagram illustrating a configuration example of a memory cell according to the embodiment.

FIG. 3 is a diagram illustrating a configuration example of a fuse element according to the embodiment.

FIG. 4 is a graph illustrating blow characteristics of the fuse element according to the embodiment.

FIG. 5 is a diagram illustrating a configuration example of a memory cell according to a comparative example of the embodiment.

FIG. 6 is a diagram illustrating a configuration example of a fuse element according to the comparative example of the embodiment.

FIG. 7 is a graph illustrating blow characteristics of the fuse element according to the comparative example of the embodiment.

FIG. 8 is a view for describing a circuit area comparison between the memory cell according to the embodiment and the memory cell of the comparative example.

FIG. 9 is a diagram illustrating a configuration example of a fuse element according to a first modification of the embodiment.

FIG. 10 is a diagram illustrating a configuration example of a fuse element according to a second modification of the embodiment.

FIG. 11 is a diagram illustrating a configuration example of a fuse element according to a third modification of the embodiment.

FIG. 12 is a diagram illustrating a configuration example of a memory cell according to a third modification of the embodiment.

FIG. 13 is a diagram illustrating a configuration example of a fuse element according to a fourth modification of the embodiment.

FIG. 14 is a diagram illustrating a configuration example of a memory cell according to the fourth modification of the embodiment.

FIG. 15 is a diagram illustrating a configuration example of an imaging device.

FIG. 16 is a diagram illustrating a configuration example of a distance measurement device.

### DESCRIPTION OF EMBODIMENTS

Hereinafter, embodiments of the present disclosure will be described in detail with reference to the drawings. Note that a device, an apparatus, a system, a method, and the like according to the present disclosure are not limited by the embodiments. Further, the same portions are basically denoted by the same reference signs in each of the following embodiments, and a repetitive description thereof will be omitted.

One or a plurality of embodiments (including examples and modifications) to be described hereinafter can be implemented independently. Meanwhile, at least some of the plurality of embodiments to be described hereinafter may be implemented appropriately in combination with at least some of other embodiments. The plurality of embodiments may include novel features different from each other. Therefore, the plurality of embodiments can contribute to achieving mutually different objects or solutions to problems, and can exhibit mutually different effects.

The present disclosure will be described in the following item order.

### 1. Embodiment

1-1. Configuration Example of Semiconductor Memory Device

1-2. Configuration Example of Memory Cell of Embodiment

1-3. Configuration Example of Memory Cell of Comparative Example

1-4. Comparison of Circuit Area of Memory Cell between Present Embodiment and Comparative Example

1-5. Modifications of Fuse Element

1-5-1. First Modification

1-5-2. Second Modification

1-5-3. Third Modification

1-5-4. Fourth Modification

1-6. Action and Effect

2. Other Embodiments

3. Configuration Example of Electronic Apparatus

3-1. Imaging Device

3-2. Distance Measurement Device

4. Appendix

### 1. Embodiment

### <1-1. Configuration Example of Semiconductor Memory Device>

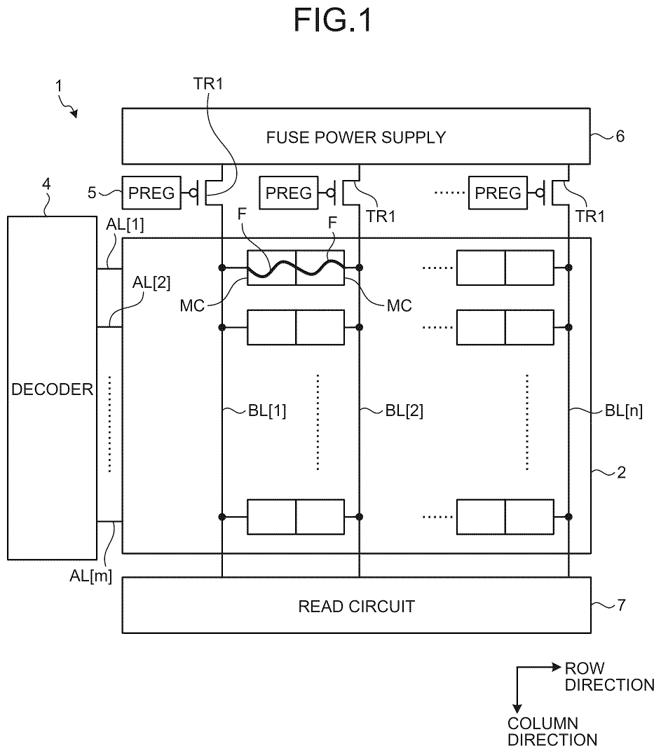

A configuration example of a semiconductor memory device 1 according to the present embodiment will be described with reference to FIG. 1. FIG. 1 is a diagram illustrating the configuration example of the semiconductor memory device 1 according to the present embodiment. Meanwhile, FIG. 1 illustrates only the main part of the semiconductor memory device 1. The semiconductor memory device 1 is an example of a semiconductor device.

As illustrated in FIG. 1, the semiconductor memory device 1 according to the present embodiment includes a memory cell array 2, a decoder 4, a plurality of pattern registers (PREG) 5, a fuse power supply 6, a read circuit 7, and a plurality of fuse transistors TR1.

The memory cell array 2 includes m (rows)×n (columns) memory cells MC arrayed in a matrix. In the present embodiment, m and n are integers of two or more, but for example, m may be one and n may be an integer of two or more. Note that the semiconductor memory device 1 has a function of selecting a desired memory cell MC from the memory cells MC, a function of writing data to the selected memory cell MC, and a function of reading data from the selected memory cell MC.

One memory cell MC has a fuse element F as a memory element, and can store 1-bit data (“0” or “1”). Two memory cells MC constitute one set. In the set of memory cells MC, one ends (anodes and cathodes) of the respective fuse elements F are connected to each other, and the other ends (cathodes or anodes) are connected to mutually different bit lines BLn (n=1, 2, and so on).

In the example of FIG. 1, only the fuse element F is simply illustrated in the memory cell MC. The fuse element F is, for example, an electrical fuse element (eFUSE) whose resistance value can be electrically controlled in an irreversible manner. Hereinafter, a description will be given assuming that the fuse element F is, for example, the electrical fuse element. For example, when a large current flows through the fuse element F, a composition of a wiring material is changed, so that the resistance value thereof is remarkably increased. Hereinafter, causing the large current to flow through the fuse element F is also referred to as “blow”. For example, when the fuse element F is blown, the resistance value thereof changes from a low resistance value (for example, about 100 Ω) to a high resistance value (for example, about 5 kΩ). The low resistance value refers to an initial resistance value before the current flows through the fuse element F. The high resistance value refers to a resistance value after the fuse element F is blown.

Note that a state (first state) in which the resistance value of the fuse element F is the low resistance value is associated with “0” and also referred to as an “unwritten state”. On the other hand, a state (second state) in which the resistance value of the fuse element F is the high resistance value is associated with “1” and also referred to as a “written state”.

The memory cell MC having the above fuse element F stores one-bit data of “0” or “1” depending on the resistance value of the fuse element F. For this reason, changing the resistance value of the fuse element F from the low resistance value to the high resistance value is also simply referred to as “writing (of the memory cell MC)” or “programming”.

The decoder 4 controls an operation of each of the memory cells MC of the memory cell array 2. The decoder 4 has, for example, a function of selecting a bit select line (word line) ALm (m=1, 2, and so on), and selects read target and write target memory cells MC.

Each of the pattern registers 5 is arranged for each column, and for example, n pattern registers 5 are provided. These pattern registers 5 are connected to gates of the fuse transistors TR1 of the corresponding columns, respectively, to control on/off of the fuse transistors TR1. Each of the fuse transistors TR1 is, for example, a p-channel metal oxide semiconductor (PMOS) transistor.

The fuse power supply 6 is connected in common to sources of the respective fuse transistors TR1. The fuse power supply 6 supplies a fuse power supply voltage VFUSE (>a power supply voltage VDD) for biasing the fuse element F to the fuse element F during writing of the memory cell MC.

The read circuit 7 performs reading of data from the read target memory cell MC. Note that the fuse element F is biased during reading of the memory cell MC. Then, the resistance value of the fuse element F of the memory cell MC, that is, “0” or “1” is read by the read circuit 7 by a comparison between a voltage output to the bit line BLn and a reference voltage.

The fuse transistor TR1 has a gate connected to the pattern register 5, a source connected to the fuse power supply 6, and a drain connected to the bit line BLn. The pattern register 5 supplies a control signal FB to the fuse transistor TR1. The fuse transistor TR1 is supplied with the control signal FB at a low level=L, for example, and turned on during writing of the memory cell MC.

Note that the pattern register 5 is arranged for each column in the example of FIG. 1, but is not limited thereto. For example, the decoder 4 may control on/off of each of the fuse transistors TR1 without arranging the pattern register 5 for each column. Alternatively, a new decoder different from the decoder 4 may be separately provided instead of the pattern register 5, and this decoder may control on/off of each of the fuse transistors TR1. In such a case, it suffices that the decoder 4 or the new decoder supplies the control signal FB to the fuse transistor TR1.

### <1-2. Configuration Example of Memory Cell of Embodiment>

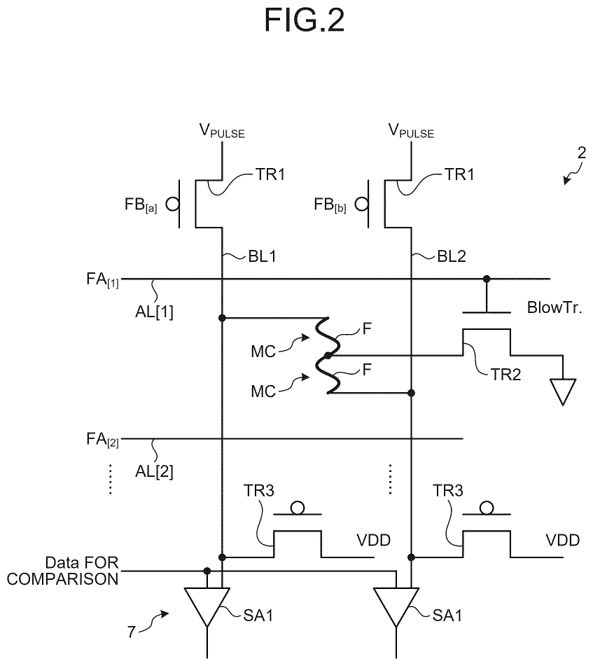

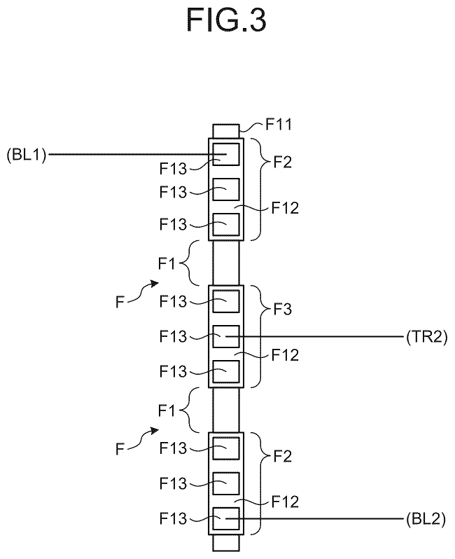

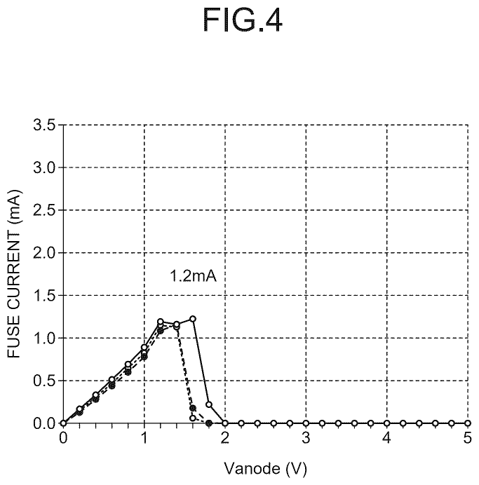

A configuration example of the memory cell MC according to the present embodiment will be described with reference to FIGS. 2 to 4. FIG. 2 is a diagram illustrating the configuration example of the memory cell MC according to the present embodiment. FIG. 3 is a diagram illustrating a configuration example of the fuse element F according to the present embodiment. FIG. 4 is a graph illustrating blow characteristics (a relationship between a fuse current and an anode voltage) of the fuse element F according to the present embodiment.

As illustrated in FIG. 2, the set of memory cells MC includes the fuse elements F of the respective memory cells MC and a blow transistor (BlowTr.) TR2 common to the memory cells MC. The blow transistor TR2 is connected in common to, that is, to be shared by the memory cells MC. Note that the blow transistor TR2 is an example of a selection element and corresponds to a selection transistor.

As illustrated in FIG. 3, the fuse element F includes a filament F1, an anode (anode terminal) F2, and a cathode (cathode terminal) F3. Two fuse elements F constitute one set. The set of fuse elements F shares the cathode F3.

For example, the set of fuse elements F includes a gate wiring F11, a plurality of wirings (wiring layers) F12, and a plurality of contacts F13. The gate wiring F11, the wirings F12, and the contacts F13 are laminated, for example.

The gate wiring F11 is formed in, for example, a single linear shape (rectangular shape) and includes the filament F1. Each of the wirings F12 includes an anode wiring for forming the anode F2 and a cathode wiring for forming the cathode F3. Each of the contacts F13 is a region to which another wiring (for example, a wiring to the bit line BLn, the blow transistor TR2, or the like) is connected.

In the example of FIGS. 2 and 3, in the set of fuse elements F, the anode F2 of one fuse element F is connected to a bit line BL1, and the anode F2 of the other fuse element F is connected to a bit line BL2. The shared cathode F3 of the set of fuse elements F is connected to a drain of the blow transistor TR2. As a result, the blow transistor TR2 is shared by the set of fuse elements F.

The blow transistor TR2 switches each set of the plurality of sets of fuse elements F between a conduction target and a non-conduction target. For example, the blow transistor TR2 is an n-channel metal oxide semiconductor (NMOS) transistor. In the blow transistor TR2, a gate is connected to the bit select line ALm, and a source is grounded (for example, set to a ground potential GND). The bit select line ALm has one end connected to the decoder 4, and is supplied with a bit selection signal FAm (m=1, 2, and so on) by the decoder 4.

During writing of the memory cell MC, that is, when the fuse element F is blown, the bit selection signal FAm at a high level=H is supplied to the bit select line ALm, and the blow transistor TR2 is turned on. The blow transistor TR2 is also turned on during reading of the memory cell MC. Note that the fuse element F is biased by the fuse power supply voltage VFUSE or the power supply voltage VDD when the blow transistor TR2 is turned on.

The read circuit 7 includes a bit line selection transistor (reading bit selection transistor) TR3 and a comparator SA1. The bit line selection transistor TR3 and the comparator SAL are arranged for each column. The read circuit 7 reads data from the read target memory cell MC.

The bit line selection transistor TR3 controls the supply of the power supply voltage VDD to the bit line BLn. The bit line selection transistor TR3 is, for example, a PMOS transistor. The bit line selection transistor TR3 has a source connected to a VDD line and a drain connected to the bit line BLn. The bit line selection transistor TR3 is turned on when a control signal at a high level is supplied to a gate thereof during reading of the memory cell MC. When the bit line selection transistor TR3 is turned on in this manner, the bit line BLn is selected.

The comparator SA1 is, for example, a latch-type sense amplifier that performs a voltage comparison. The comparator SA1 detects a potential of the bit line BLn. For example, the comparator SA1 compares a voltage V=V1 of the memory cell MC with a reference voltage Vref (data for comparison) and reads a state of the memory cell MC. As a result of this comparison, in a case where the voltage V=V1 is lower than the reference voltage Vref (V1<Vref), “0” is read. On the other hand, in a case where the voltage V=V1 is higher than the reference voltage Vref (V1>Vref), “1” is read.

Here, normally, examples of the material used for the fuse element F that is One Time Programmable (OTP) include polysilicon (PolySi), but it is difficult to have a structure in which the anode F2 or the cathode F3 of the plurality of fuse elements F is shared in the OTP using PolySi. This is because a current of about 2 to 3 mA is required to cause electromigration in the filament F1 portion of the fuse element F. When it is necessary to cause a large current to flow, electromigration may be caused in a contact or a VIA (via wiring) other than the filament F1 portion so that a circuit is damaged.

In order to cope with this, a High-k Metal Gate (HKMG) is used for the fuse element F in the present embodiment. As a result, an extremely thin pattern can be used since a metal is used for a gate electrode, and electromigration can be caused in the filament F1 portion at a current of, for example, 1.2 mA, that is, about 1 mA in the fuse element F as illustrated in FIG. 4. Note that the relationship between the fuse current (mA) and the anode voltage (V) in a case where W (width)/L (length) of the fuse element F is 30/200 nm (W/L=30/200 nm) is illustrated in the example of FIG. 4. It is possible to create a circuit in which the number of the blow transistors TR2 is halved by using the HKMG for the fuse element F and sharing the cathode F3 in the set of fuse elements F.

Here, the HKMG has a structure in which a High-k material (high dielectric constant material) is used for a gate insulating film and the metal (Metal Gate) is used for the gate electrode, and in short, has a structure of High-k material +Metal Gate. Specifically, the gate insulating film is a thin film-like insulating layer sandwiched between the gate electrode and a substrate (wafer) made of silicon or the like. As a material of the gate insulating film, silicon dioxide (SiO₂: silica) is generally used, but the High-k material having a relative dielectric constant higher than that of silicon dioxide is used in the HKMG. As a result, the gate insulating film can be formed to be thicker while maintaining performance and characteristics of a transistor, and leakage of a current (a leakage current) passing through the insulating film can be reduced by a quantum tunnel effect. Note that examples of the High-k material include hafnium-based, tungsten-based, and cobalt-based materials.

### <1-3. Configuration Example of Memory Cell of Comparative Example>

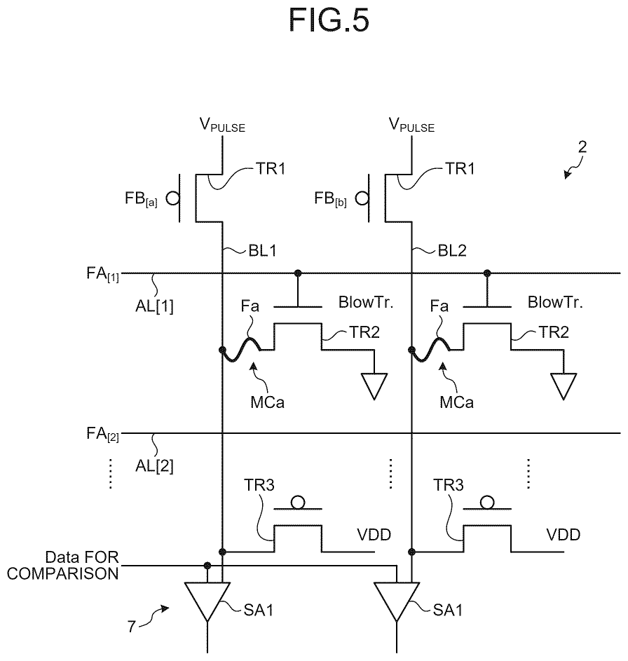

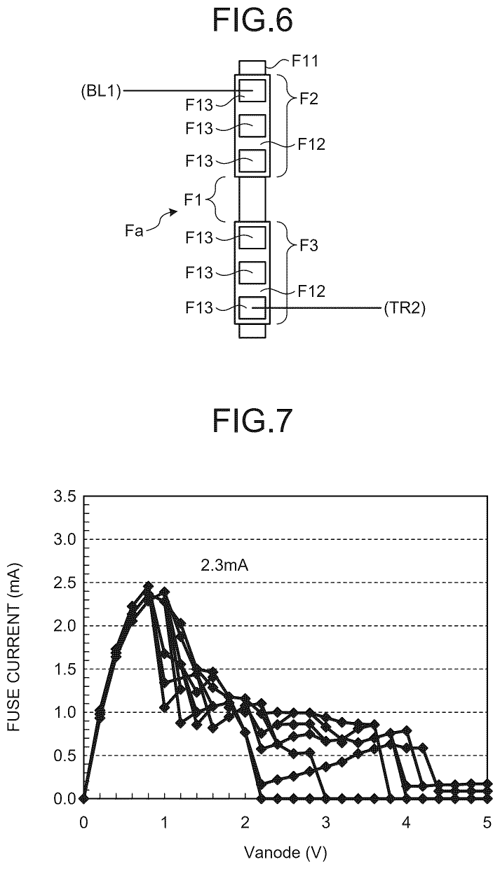

A configuration example of a memory cell MCa according to a comparative example of the present embodiment will be described with reference to FIGS. 5 to 7. FIG. 5 is a diagram illustrating the configuration example of a memory cell MCa according to the comparative example of the present embodiment. FIG. 6 is a diagram illustrating a configuration example of a fuse element Fa according to the comparative example of the present embodiment. FIG. 7 is a graph for describing blow characteristics (a relationship between a fuse current and an anode voltage) of the fuse element Fa according to the comparative example of the present embodiment.

As illustrated in FIG. 5, the memory cell MCa of the comparative example includes one fuse element Fa and one blow transistor (BlowTr) TR2.

As illustrated in FIG. 6, the fuse element Fa of the comparative example includes the filament F1, the anode F2, and the cathode F3. As a material of the fuse element F, for example, polysilicon (polySi) is used. Note that the fuse element F of the comparative example also includes the gate wiring F11, the plurality of wirings (wiring layers) F12, and the plurality of contacts F13 as in the present embodiment.

In the examples of FIGS. 5 and 6, the anode F2 of the fuse element Fa is connected to the bit line BL1, and the cathode F3 of the fuse element Fa is connected to the drain of the blow transistor TR2. Note that other configurations are similar to those in FIG. 2, and thus, the description thereof will be omitted.

As illustrated in FIG. 7, the fuse element Fa of the comparative example can cause electromigration in the filament F1 portion with a current of, for example, 2.3 mA, that is, about 2 to 3 mA. Note that the relationship between the fuse current (mA) and the anode voltage (V) in a case where W (width)/L (length) of the fuse element Fa is 70/600 nm (W/L=70/600 nm) is illustrated in the example of FIG. 7.

The above current of about 2 to 3 mA is a large current approximately twice as large as that of the fuse element F (for example, 1.2 mA) according to the present embodiment. When it is necessary to cause a large current to flow to cause electromigration in the filament F1 portion in this manner, electromigration may be caused in a contact or a VIA (via wiring) other than the filament F1 portion so that a circuit is damaged. Therefore, the damage to the circuit can be avoided by using the fuse element F according to the present embodiment.

<1-4. Comparison of Circuit Area of Memory Cell between Present Embodiment and Comparative Example>

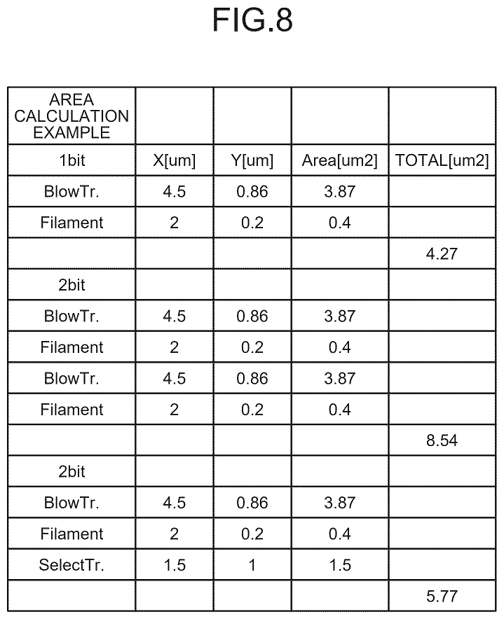

A circuit area comparison between the memory cell MC according to the present embodiment and the memory cell MCa of the comparative example will be described with reference to FIG. 8. FIG. 8 is a view for describing the circuit area comparison between the memory cell MC according to the present embodiment and the memory cell MCa of the comparative example.

As illustrated in FIG. 8, there are three area

measurement examples (measurement results). The first area measurement example (in upper rows in FIG. 8) is a case where the memory cell MCa of the comparative example corresponding to one bit is used. The second area measurement example (in middle rows in FIG. 8) is a case where the memory cells MCa of the comparative example corresponding to two bits are used (see FIG. 5). The third area measurement example (in lower rows in FIG. 8) is a case where the memory cell MC of the present embodiment corresponding to two bits is used (see FIG. 2).

In the first area measurement example, for one bit (1bit), the area (Area) of the blow transistor TR2 (BlowTr.) is 3.87, the area (Area) of the filament F1 is 0.4, and the total is 4.27.

In the second area measurement example, twice the result of the first area measurement example is obtained for two bits (2bit). That is, the area (Area) of one blow transistor TR2 (BlowTr.) is 3.87, the area (Area) of one filament F1 is 0.4, and there is another set of both, so that the total is 8.54 (=4.27×2).

In the third area measurement example, for two bits (2bit), the area (Area) of one blow transistor TR2 (BlowTr.) is 3.87, the area (Area) of one filament F1 is 0.4, the area (Area) of a select transistor (SelectTr.) is 1.5, and the total is 5.77. Note that the select transistor is, for example, a portion (for example, two anodes F2 and one cathode F3) other than the filament F1 in the fuse element F (see FIG. 3).

According to such measurement examples, the total area in the case of using the memory cells MCa of the comparative example corresponding to two bits is 8.54, and the total area in the case of using the memory cell MC of the present embodiment corresponding to two bits is 5.77. From these estimations of the circuit area comparison, it can be understood that, when the memory cell MC of the present embodiment corresponding to two bits is used, the circuit area can be reduced by about 35% with respect to the memory cells MCa of the comparative example corresponding to two bits.

### <1-5. Modifications of Fuse Element>

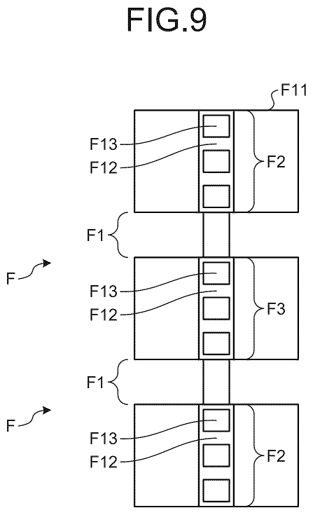

Modifications of the fuse element F according to the present embodiment will be described with reference to FIGS. 9 to 14. FIGS. 9 to 14 are diagrams for describing the modifications of the fuse element F according to the present embodiment.

### <1-5-1. First Modification>

A configuration example of the fuse element F according to a first modification of the present embodiment will be described with reference to FIG. 9. FIG. 9 is a diagram illustrating the configuration example of the fuse element F according to the first modification of the present embodiment.

As illustrated in FIG. 9, in the first modification, the gate wiring F11 of the set of fuse elements F is not formed in a single linear shape, that is, a quadrilateral shape such as a rectangular shape, but is formed in a shape in which a portion other than the filament F1 is larger (wider) than a line width of the filament F1. As a result, it is possible to perform adjustment such as making the filament F1 easily cut or difficult to cut by appropriately changing a line width of the gate wiring F11. Note that the shape of the gate wiring F11 is not particularly limited.

### <1-5-2. Second Modification>

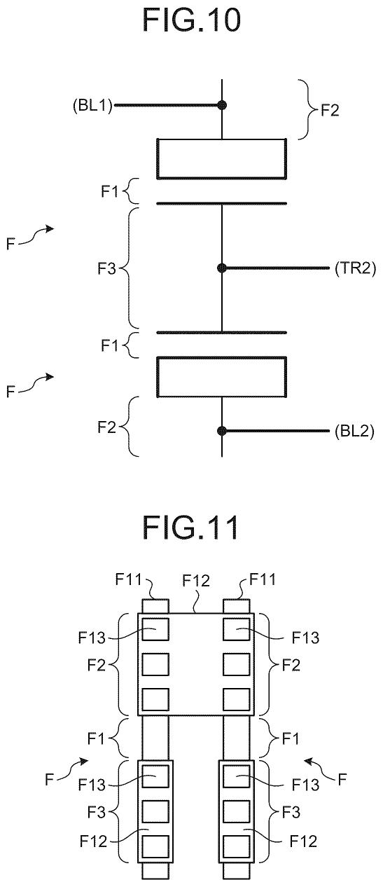

A configuration example of the fuse element F according to a second modification of the present embodiment will be described with reference to FIG. 10. FIG. 10 is a diagram illustrating the configuration example of the fuse element F according to the second modification of to the present embodiment.

As illustrated in FIG. 10, the fuse element F is an anti-fuse element in the second modification. In the example of FIG. 10, the fuse element F of the second modification is, for example, an anti-fuse element using breakdown of an insulating film. The anti-fuse element is generally a switch element that exhibits an electrically non-conductive state in an initial state, and can irreversibly transition from the non-conductive state to a conductive state using an electrical method.

Specifically, the anti-fuse element includes, for example, a pair of electrodes formed in two different wiring layers and a dielectric inserted therebetween and exhibiting insulation (or high resistance). A high voltage is applied to the above electrodes to program the dielectric (to transition from the non-conductive state to the conductive state by dielectric breakdown) and to electrically connect the wiring layers. Note that, as the anti-fuse element, there is also a fuse element utilizing a magnetic tunnel junction (MTJ) element.

### <1-5-3. Third Modification>

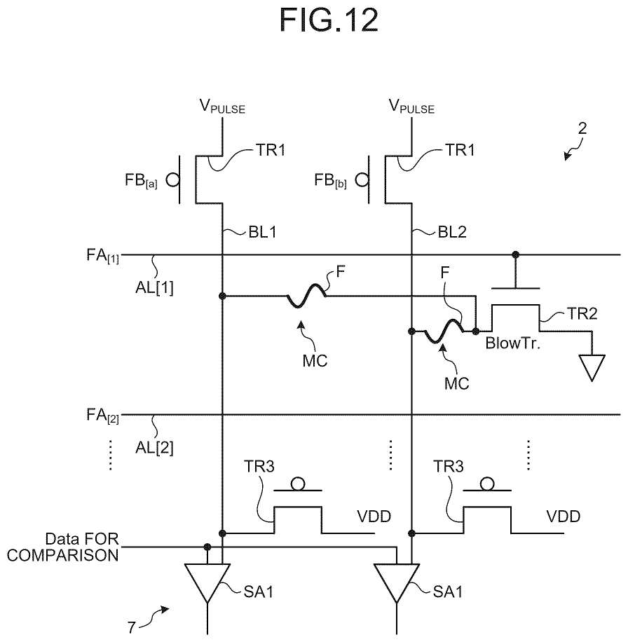

A configuration example of the fuse element F according to a third modification of the present embodiment will be described with reference to FIGS. 11 and 12. FIG. 11 is a diagram illustrating the configuration example of the fuse element F according to the third modification of the present embodiment. FIG. 12 is a diagram illustrating a configuration example of the memory cell MC according to the third modification of the present embodiment.

As illustrated in FIGS. 11 and 12, in the third modification, two fuse elements F are electrically connected by one wiring F12. The wiring F12 connects the anodes F2 of the two fuse elements F. The two fuse elements F connected by the wiring F12 constitute one set. The blow transistor TR2 is provided in common to the set of fuse elements F.

Note that the blow transistor TR2 does not exist between the bit line BL1 and the bit line BL2 as illustrated in FIG. 12, and thus, for example, a separation distance between the bit line BL1 and the bit line BL2 can be narrowed in such a region. Alternatively, another element can also be arranged in the region.

### <1-5-4. Fourth Modification>

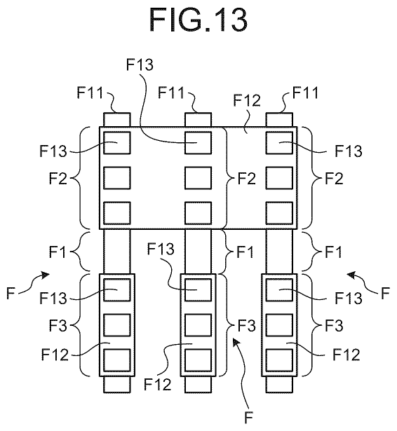

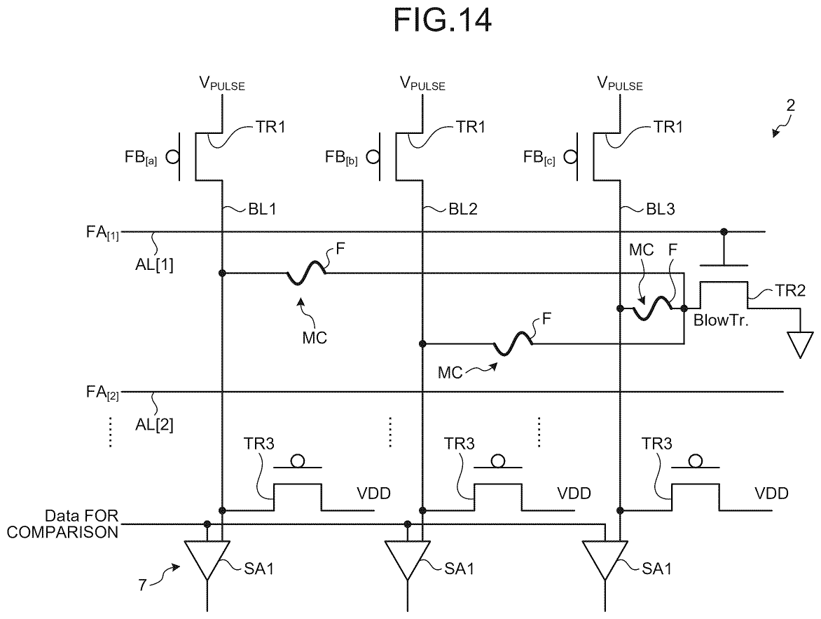

A configuration example of the fuse element F according to a fourth modification of the embodiment will be described with reference to FIGS. 13 and 14. FIG. 13 is a diagram illustrating the configuration example of the fuse element F according to the fourth modification of the embodiment. FIG. 14 is a diagram illustrating a configuration example of the memory cell MC according to the fourth modification of the embodiment. As illustrated in FIGS. 13 and 14, in the fourth modification, three fuse elements F are electrically connected by one wiring F12. The wiring F12 connects the anodes F2 of the three fuse elements F. The three fuse elements F connected by the wiring F12 constitute one set. The blow transistor TR2 is provided in common to the set of fuse elements F.

Note that the blow transistor TR2 does not exist between the bit line BL1 and the bit line BL2 and between the bit line BL2 and a bit line BL3 as illustrated in FIG. 14, and thus, for example, the separation distance between the bit line BL1 and the bit line BL2 and a separation distance between the bit line BL2 and the bit line BL3 can be narrowed in such a region. Alternatively, another element can also be arranged in the region.

### <1-6. Action and Effect>

As described above, according to the present embodiment, the semiconductor memory device 1, which is an example of the semiconductor device, includes the plurality of fuse elements F and the selection element (for example, the blow transistor TR2) which is provided in common to the fuse elements F and switches each of the fuse elements F to a conduction target and a non-conduction target. As a result, since the selection element is used in common to the respective fuse elements F, the number and occupied area (for example, installation area) of the selection elements can be suppressed. Therefore, it is possible to reduce the number and the occupied area of the selection elements.

Further, each of the fuse elements F may have the filament F1, the anode F2, and the cathode F3, and the respective fuse elements F may share the anode F2 or the cathode F3 (see FIG. 3). As a result, the selection element can be reliably provided in common to the respective fuse elements F.

Further, the selection element may be a selection transistor (for example, the blow transistor TR2) having a drain and a source, and the drain or the source of the selection transistor may be connected to the anode F2 or the cathode F3 shared by the respective fuse elements F (see FIG. 3). As a result, the selection transistor can be reliably provided in common to the respective fuse elements F.

Further, each of the fuse elements F may have the gate wiring F11 including the filament F1 of each of the fuse elements F and the plurality of wirings F12 configured to form the anodes F2 of the fuse elements F and the cathode F3 shared by the respective fuse elements F or to form the cathode F3 of the fuse elements F and the anode F2 shared by the respective fuse elements F (see FIG. 3). As a result, it is possible to reliably form a set of the fuse elements F sharing the cathode F3 or the anode F2.

Further, the gate wiring F11 may be formed in a shape in which a line width of each of the fuse elements F other than the filament F1 is larger (wider) than a line width of each of the filaments F1 (see FIG. 9). As a result, it is possible to perform adjustment such as making the filament F1 easily cut or difficult to cut by appropriately changing a line width of the gate wiring F11.

Further, each of the fuse elements F may have the filament F1, the anode F2, and the cathode F3, and the anodes F2 or the cathodes F3 of the respective fuse elements F may be connected by the wiring F12 (see FIGS. 11 and 13). As a result, the selection element can be reliably provided in common to the respective fuse elements F.

Further, each of the fuse elements F may have the gate wiring F11 including the filament F1 and the plurality of wirings F12 configured to form the anode F2 and the cathode F3, and each of the wirings F12 may include the wiring F12 connecting the anodes F2 or the cathodes F3 of the respective fuse elements F (see FIGS. 11 and 13). As a result, it is possible to reliably form a set of the fuse elements F sharing the cathode F3 or the anode F2.

Further, each of the fuse elements F may be formed in a High-k Metal Gate (HKMG) structure. As a result, it is possible to suppress a current to be supplied to each of the fuse elements F, and thus, it is possible to suppress damage to a circuit.

Further, each of the fuse elements F may be an electrical fuse element whose resistance is changed by application of a voltage. This enables reliable writing.

Each of the fuse elements F may be an electrical fuse element in which electromigration is caused by application of a voltage. This enables reliable writing.

Further, each of the selection elements may be a selection transistor (for example, the blow transistor TR2) that switches each of the fuse elements F to a voltage application target and a voltage non-application target. This enables reliable switching.

Further, the semiconductor memory device 1 may further include a cell array (for example, the memory cell array 2) having a plurality of cells (for example, the memory cells MC), and the respective cells may have the fuse elements F, respectively, and share a selection element. As a result, the number and the occupied area of the selection elements can be reduced also when the cell array having the plurality of cells is used.

### <2. Other Embodiments>

The processing according to the embodiment (or the modifications) described above may be performed in various different aspects (modifications) other than the embodiment described above. For example, among each process described in the embodiment described above, all or a part of the processes described as being performed automatically may be manually performed or the processes described as being performed manually can be performed automatically by the known method. In addition, the processing procedures, specific names, and information including various data and parameters illustrated in the above documents and drawings can be arbitrarily changed unless otherwise specified. For example, various types of information illustrated in each drawing are not limited to the illustrated information.

Further, each component of each device illustrated is a functional concept, and does not necessarily need to be physically configured as illustrated. That is, the specific form of distribution/integration of each device is not limited to those illustrated in the drawings, and all or a part thereof may be functionally or physically distributed/integrated into arbitrary units according to various loads and usage situations.

In addition, the embodiment (or the modifications) described above can be appropriately combined within a range not causing inconsistency in processing content. Further, the effects described in the present specification are merely examples and are not restrictive of the disclosure herein, and other effects not described herein may be achieved.

### <3. Configuration Example of Electronic Apparatus>

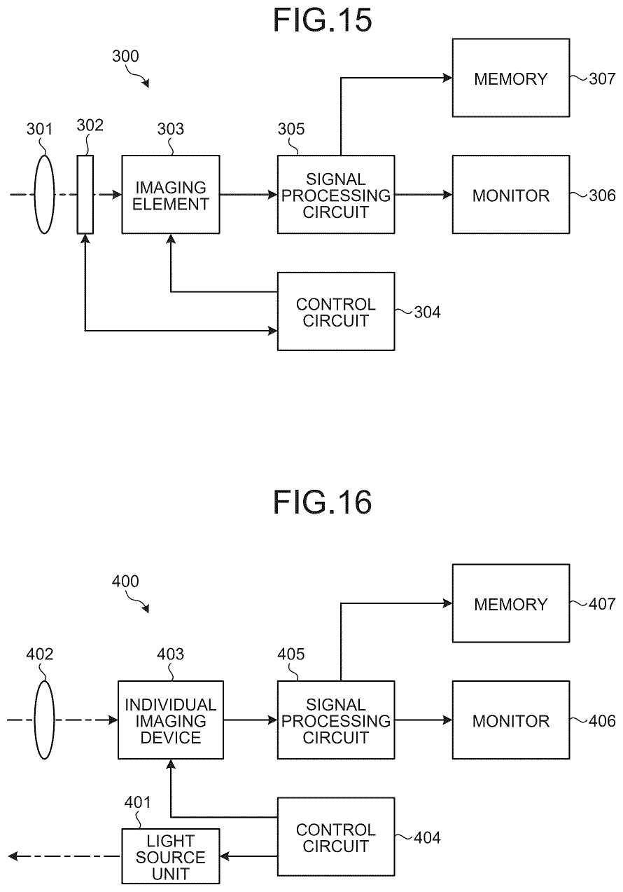

As an electronic apparatus to which the semiconductor memory device 1 according to the above embodiment (including the modifications) is applied, an imaging device 300 and a distance measurement device 400 will be described with reference to FIGS. 15 and 16. For example, the imaging device 300 and the distance measurement device 400 use the semiconductor memory device 1 according to the above embodiment as a memory.

### <3-1. Imaging Device>

The imaging device 300 to which the semiconductor memory system 1 according to the above embodiment is applied will be described with reference to FIG. 15. FIG. 15 is a diagram illustrating an example of a schematic configuration of the imaging device 300. The imaging device 300 is an example of the electronic apparatus to which the semiconductor memory system 1 according to the present embodiment is applied. Examples of the imaging device 300 include electronic devices such as a digital still camera, a video camera, a smartphone having an imaging function, and a mobile phone.

As illustrated in FIG. 15, the imaging device 300 includes an optical system 301, a shutter device 302, an imaging element 303, a control circuit (drive circuit) 304, a signal processing circuit 305, a monitor 306, and a memory 307. The imaging device 300 can capture a still image and a moving image.

The optical system 301 includes one or a plurality of lenses. The optical system 301 guides light (incident light) from a subject to the imaging element 303 and forms an image on a light receiving surface of the imaging element 303.

The shutter device 302 is disposed between the optical system 301 and the imaging element 303. The shutter device 302 controls a light irradiation period and a light shielding period with respect to the imaging element 303 according to the control of the control circuit 304.

The imaging element 303 accumulates signal charges for a certain period according to light formed on the light receiving surface via the optical system 301 and the shutter device 302. The signal charges accumulated in the imaging element 303 is transferred in accordance with a drive signal (timing signal) supplied from the control circuit 304.

The control circuit 304 outputs the drive signal for controlling a transfer operation of the imaging element 303 and a shutter operation of the shutter device 302 to drive the imaging element 303 and the shutter device 302.

The signal processing circuit 305 performs various types of signal processing on the signal charges output from the imaging element 303. An image (image data) obtained by performing the signal processing by the signal processing circuit 305 is supplied to the monitor 306 and also supplied to the memory 307.

The monitor 306 displays a moving image or a still image captured by the imaging element 303 based on the image data supplied from the signal processing circuit 305. As the monitor 306, for example, a panel type display device such as a liquid crystal panel or an organic electro luminescence (EL) panel is used.

The memory 307 stores the image data supplied from the signal processing circuit 305, that is, image data of the moving image or the still image captured by the imaging element 303. The memory 307 corresponds to the semiconductor memory device 1 according to the above embodiment.

Also in the imaging device 300 configured in this manner, it is possible to reduce the number and the occupied area of the elements by using the above-described semiconductor memory system 1 as the memory 307.

### <3-2. Distance Measurement Device>

The distance measurement device 400 to which the semiconductor memory system 1 according to the above embodiment is applied will be described with reference to FIG. 16. FIG. 16 is a diagram illustrating an example of a schematic configuration of the distance measurement device 400. The distance measurement device 400 is an example of the electronic apparatus to which the semiconductor memory system 1 according to the present embodiment is applied.

As illustrated in FIG. 16, the distance measurement device (distance image sensor) 400 includes a light source unit 401, an optical system 402, a solid-state imaging device (imaging element) 403, a control circuit (drive circuit) 404, a signal processing circuit 405, a monitor 406, and a memory 407. The distance measurement device 400 can acquire a distance image according to a distance to a subject by projecting light from the light source unit 401 toward the subject and receiving light (modulated light or pulsed light) reflected from a surface of the subject.

The light source unit 401 projects light toward the subject. As the light source unit 401, for example, a vertical cavity surface emitting laser (VCSEL) array that emits laser light as a surface light source or a laser diode array in which laser diodes are arrayed on a line is used. Note that the laser diode array is supported by a predetermined drive unit (not illustrated), and is scanned in a direction perpendicular to the array direction of the laser diodes.

The optical system 402 includes one or a plurality of lenses. The optical system 402 guides light (incident light) from the subject to the solid-state imaging device 403 to form an image on a light receiving surface (sensor unit) of the solid-state imaging device 403.

The solid-state imaging device 403 stores signal charges according to the light of the image formed on the light receiving surface via the optical system 402. A distance signal indicating the distance obtained from a light reception signal (APD OUT) output from the solid-state imaging device 403 is supplied to the signal processing circuit 405. As the solid-state imaging device 403, for example, a solid-state imaging element such as an image sensor is used.

The control circuit 404 outputs a drive signal (control signal) for controlling operations of the light source unit 401, the solid-state imaging device 403, and the like to drive the light source unit 401, the solid-state imaging device 403, and the like.

The signal processing circuit 405 performs various types of signal processing on the distance signal supplied from the solid-state imaging device 403. For example, the signal processing circuit 405 performs image processing (for example, histogram processing, peak detection processing, and the like) of constructing the distance image on the basis of the distance signal. An image (image data) obtained by performing the signal processing by the signal processing circuit 405 is supplied to the monitor 406 and also supplied to the memory 407.

The monitor 406 displays the distance image captured by the imaging element 303 on the basis of the image data supplied from the signal processing circuit 405. As the monitor 406, for example, a panel type display device such as a liquid crystal panel or an organic EL panel is used.

The memory 407 stores the image data supplied from the signal processing circuit 405, that is, the image data of the distance image captured by the imaging element 303. The memory 407 corresponds to the semiconductor memory system 1 according to the above embodiment.

Also in the distance measurement device 400 configured in this manner, it is possible to reduce the number and the occupied area of the elements by using the above-described semiconductor memory system 1 as the memory 407.

It is noted that the semiconductor memory system 1 according to each of the above-described embodiments may be mounted on the same semiconductor chip together with a semiconductor circuit forming an arithmetic device or the like to form a semiconductor device (System-on-a-Chip: SoC).

Furthermore, the semiconductor memory system 1 according to the above embodiment can be mounted on various electronic devices on which a memory (storage unit) can be mounted as described above. For example, the semiconductor memory system 1 may be mounted on various electronic devices such as a game device, a hard disk drive (HDD), a notebook personal computer (PC), a mobile device (for example, a smartphone, a tablet PC, or the like), a personal digital assistant (PDA), a wearable device, and a music device in addition to the imaging device 300.

### <4. Appendix>

Note that the present technology can also have the following configurations.

(1)

A semiconductor device comprising:
a plurality of fuse elements; and
a selection element that is provided in common to the plurality of fuse elements and switches the plurality of fuse elements between a conduction target and a non-conduction target.

(2)

The semiconductor device according to (1), wherein
the plurality of fuse elements each include a filament, an anode, and a cathode, and
the plurality of fuse elements share the anode or the cathode.

(3)

The semiconductor device according to (2), wherein
the selection element is a selection transistor having a drain and a source, and
the drain or the source of the selection transistor is connected to the anode or the cathode shared by the plurality of fuse elements.

(4)

The semiconductor device according to (2) or (3), wherein
the plurality of fuse elements include:
a gate wiring including the filament of each of the fuse elements; and
a plurality of wirings configured to form the anode of each of the fuse elements and the cathode shared by the plurality of fuse elements or to form the cathode of each of the fuse elements and the anode shared by the plurality of fuse elements.

(5)

The semiconductor device according to (4), wherein
the gate wiring is formed in a shape in which a line width of each of the fuse elements other than the filament is larger than a line width of the filament of each of the fuse elements.

(6)

The semiconductor device according to (1), wherein
the plurality of fuse elements each include a filament, an anode, and a cathode, and
the anodes or the cathodes of the plurality of fuse elements are connected by a wiring.

(7)

The semiconductor device according to (6), wherein
the plurality of fuse elements each include:
a gate wiring including the filament; and
a plurality of wirings configured to form the anode and the cathode, and
the plurality of wirings include the wiring connecting the anodes or the cathodes of the plurality of fuse elements.

(8)

The semiconductor device according to any one of (1) to (7), wherein
the plurality of fuse elements are formed in a High-k Metal Gate (HKMG) structure.

(9)

The semiconductor device according to any one of (1) to (8), wherein
the plurality of fuse elements are electrical fuse elements each of which resistance is changed by application of a voltage.

(10)

The semiconductor device according to (9), wherein
the plurality of fuse elements are electrical fuse elements in which electromigration is caused by application of a voltage.

(11)

The semiconductor device according to (9) or (10), wherein
the selection element is a selection transistor that switches the plurality of fuse elements to a voltage application target and a voltage non-application target.

(12)

The semiconductor device according to any one of (1) to (11), further comprising
a cell array having a plurality of cells, wherein
the plurality of cells each include the fuse element, and share the selection element.

(13)

An electronic apparatus comprising
a semiconductor device, wherein
the semiconductor device includes:
a plurality of fuse elements; and
a selection element that is provided in common to the plurality of fuse elements and switches the plurality of fuse elements between a conduction target and a non-conduction target.

(14)

An electronic apparatus including the semiconductor device according to any one of (1) to (12).

### REFERENCE SIGNS LIST

1 SEMICONDUCTOR MEMORY DEVICE

2 MEMORY CELL ARRAY

4 DECODER

5 PATTERN REGISTER

6 FUSE POWER SUPPLY

7 READ CIRCUIT

ALm BIT SELECT LINE

BLn BIT LINE

F FUSE ELEMENT

Fa FUSE ELEMENT

F1 FILAMENT

F2 ANODE

F3 CATHODE

F11 GATE WIRING

F12 WIRING

F13 CONTACT

MC MEMORY CELL

MCa MEMORY CELL

SA1 COMPARATOR

TR1 FUSE TRANSISTOR

TR2 BLOW TRANSISTOR

TR3 BIT LINE SELECTION TRANSISTOR

What is claimed is:

1. A semiconductor device comprising:
a plurality of fuse elements; and
a selection element that is provided in common to the plurality of fuse elements and switches the plurality of fuse elements between a conduction target and a non-conduction target.

2. The semiconductor device according to claim 1, wherein
the plurality of fuse elements each include a filament, an anode, and a cathode, and
the plurality of fuse elements share the anode or the cathode.

3. The semiconductor device according to claim 2, wherein
the selection element is a selection transistor having a drain and a source, and
the drain or the source of the selection transistor is connected to the anode or the cathode shared by the plurality of fuse elements.

4. The semiconductor device according to claim 2, wherein
the plurality of fuse elements include:
a gate wiring including the filament of each of the fuse elements; and
a plurality of wirings configured to form the anode of each of the fuse elements and the cathode shared by the plurality of fuse elements or to form the cathode of each of the fuse elements and the anode shared by the plurality of fuse elements.

5. The semiconductor device according to claim 4, wherein
the gate wiring is formed in a shape in which a line width of each of the fuse elements other than the filament is larger than a line width of the filament of each of the fuse elements.

6. The semiconductor device according to claim 1, wherein
the plurality of fuse elements each include a filament, an anode, and a cathode, and
the anodes or the cathodes of the plurality of fuse elements are connected by a wiring.

7. The semiconductor device according to claim 6, wherein
the plurality of fuse elements each include:
a gate wiring including the filament; and
a plurality of wirings configured to form the anode and the cathode, and
the plurality of wirings include the wiring connecting the anodes or the cathodes of the plurality of fuse elements.

8. The semiconductor device according to claim 1, wherein
the plurality of fuse elements are formed in a High-k Metal Gate (HKMG) structure.

9. The semiconductor device according to claim 1, wherein
the plurality of fuse elements are electrical fuse elements each of which resistance is changed by application of a voltage.

10. The semiconductor device according to claim 9, wherein
the plurality of fuse elements are electrical fuse elements in which electromigration is caused by application of a voltage.

11. The semiconductor device according to claim 9, wherein
the selection element is a selection transistor that switches the plurality of fuse elements to a voltage application target and a voltage non-application target.

12. The semiconductor device according to claim 1, further comprising
a cell array having a plurality of cells, wherein
the plurality of cells each include the fuse element, and share the selection element.

13. An electronic apparatus comprising
a semiconductor device, wherein
the semiconductor device includes:
a plurality of fuse elements; and
a selection element that is provided in common to the plurality of fuse elements and switches the plurality of fuse elements between a conduction target and a non-conduction target.
